(19) United States
(12) Patent Application Publication
(10) Pub. No.: US 2015/0257300 A1
(43) Pub. Date: Sep. 10, 2015

(54) ELECTRONIC DEVICE

(71) Applicant: Kabushiki Kaisha Toshiba, Minato-ku (JP)

(72) Inventor: Takashi TACHIBANA, Yokohama (JP)

(73) Assignee: Kabushiki Kaisha Toshiba, Minato-ku (JP)

(21) Appl. No.: 14/468,473

(22) Filed: Aug. 26, 2014

Related U.S. Application Data
(60) Provisional application No. 61/950,451, filed on Mar. 10, 2014.

(51) Int. Cl. H05K 7/02

(52) U.S. Cl. CPC H05K 7/02

(57) ABSTRACT

According to one embodiment, an electronic device includes a substrate, a semiconductor chip, a resin material, a housing, and an adhesive member. The semiconductor chip is provided on the substrate. The resin material covers the semiconductor chip and contacts the substrate. The housing includes a first recess portion in which at least the resin material is accommodated, a second recess portion provided in the second recess portion, a third recess portion provided in the second recess portion, and a projection provided in the periphery of the third recess portion. The adhesive member is provided at least in the first recess portion to bond the housing and the resin material to each other.

### CROSS-REFERENCE TO RELATED APPLICATIONS

This application claims the benefit of U.S. Provisional Application No. 61/950,451, filed Mar. 10, 2014, the entire contents of which are incorporated herein by reference.

### FIELD

Embodiments described herein relate generally to an electronic device such as a Universal Serial Bus (USB) memory or a memory card in which a semiconductor device of, for example, the System-in-a-Package (SiP) type is incorporated.

### BACKGROUND

A SiP type semiconductor memory device (hereinafter referred to simply as a SiP memory device) such as a NAND flash memory, comprises a resin substrate on which a plurality of semiconductor chips such as a memory and a controller are mounted, and a resin package which covers the resin substrate. This SiP memory device is accommodated in a plastic case and thus a USB memory or memory card product is produced.

### BRIEF DESCRIPTION OF THE DRAWINGS

FIG. 1 is a plan view showing an example of an electronic device according to a present embodiment;

FIG. 2 is a sectional view taken along line II-II of FIG. 1, showing a relationship between a case and a SiP memory device;

FIG. 3 is an enlarged view of a part of FIG. 2;

FIG. 4 is a plan view showing an example of an electronic device according to a comparative example; and

FIG. 5 is a sectional view taken along line V-V of FIG. 4.

### DETAILED DESCRIPTION

In general, according to one embodiment, an electronic device includes a substrate, a semiconductor chip, a resin material, a housing, and an adhesive member. The semiconductor chip is provided on the substrate. The resin material covers the semiconductor chip and contacts the substrate. The housing includes a first recess portion in which at least the resin material is accommodated, a second recess portion provided in the second recess portion, a third recess portion provided in the second recess portion, and a projection provided in the periphery of the third recess portion. The adhesive member is provided at least in the first recess portion to bond the housing and the resin material to each other.

### Embodiment

The present embodiment will now be described with reference to the accompanying drawings.

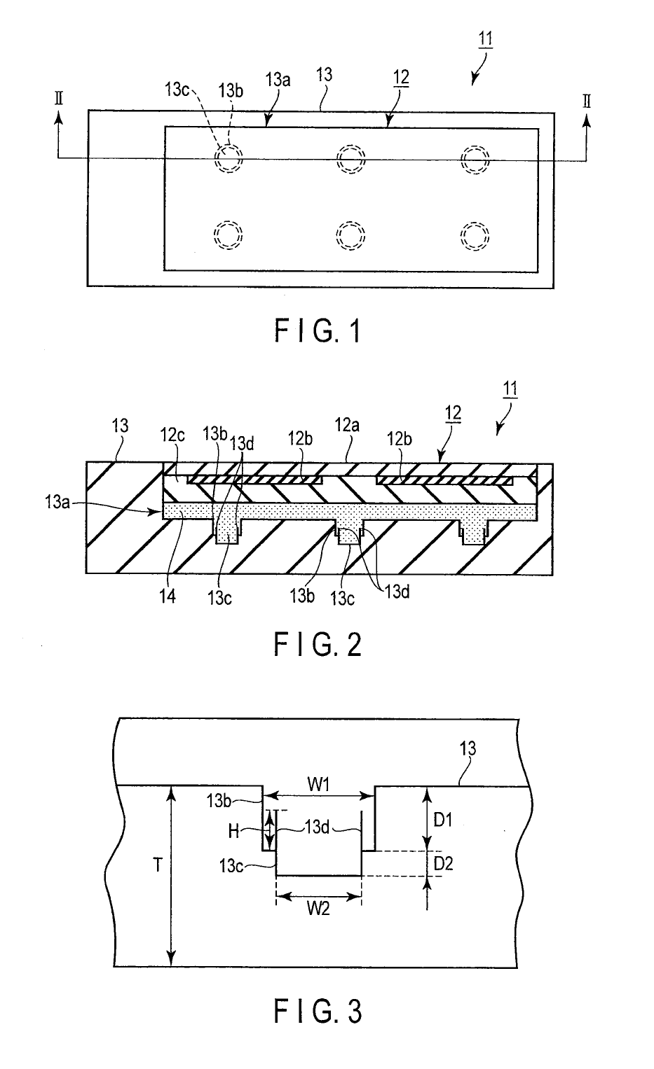

FIGS. 1 and 2 each illustrate a part of a USB memory 11 as an example of an electronic device according to the present embodiment.

In FIGS. 1 and 2, the USB memory 11 comprises a SiP memory device 12, a plastic case 13 as an example of a resin housing, and an adhesive member 14.

The SiP memory device 12 comprises, for example, a resin substrate 12a, a plurality of semiconductor chips 12b such as a memory and a controller which are mounted on the resin substrate 12a, and a resinous package 12c which covers the resin substrate 12a and the plurality of semiconductor chips 12b.

The plastic case 13 comprises a first recess portion 13a as an accommodation portion which accommodates the SiP memory device 12, a plurality of second recess portions 13b provided in a bottom portion of the first recess portion 13a, a third recess portion 13c provided in a bottom of each of the plurality of second recess portions 13b. Each third recess portion 13c is formed in such a manner as to correspond to a pin (not shown) for pushing the plastic case 13 out of a mold when the plastic case 13 is molded. In the periphery of each third recess portion 13c, a burr 13d is formed in such a manner as to correspond to the pin. As shown in FIG. 2, the burr 13d is formed as a ring projection in a gap between the metal mold and the pin (not shown).

To the bottom portion of the first recess portion 13a, an adhesive 14 as an example of an adhesive member is applied. The adhesive 14 is also applied to the inside of the second recess portion 13b and third recess portion 13c. In this state, the SiP memory device 12 is accommodated inside the first recess portion 13a. That is, the SiP memory device 12 is accommodated inside the first recess portion 13a in such a direction that the resinous package 12c of the SiP memory device 12 contacts the adhesive 14. In this state, the SiP memory device is secured to the plastic case 13 by the adhesive 14.

As described later, the depth (height) of the second recess portion 13b is set to be greater than the height of the burr 13d formed in the periphery of the third recess 13c. For this reason, the tip of the burr 13d does not project from the second recess portion 13b into the first recess portion 13a or even into the surface of the adhesive 14. Therefore, when the SiP memory device is accommodated inside the first recess portion 13a, the SiP memory device 12 is secured to the plastic case 13 stably and firmly by the adhesive member 14.

FIG. 3 specifically illustrates a relationship between the second recess 13b and the third recess portion 13c. In the present embodiment, the third recess portion 13c is formed inside the second recess portion 13b, and the depth D1 of the second recess portion 13b is set to be greater than the height H of the burr 13d. That is, when the thickness T of the plastic case 13 is 0.82 mm for example and the greatest height H of the plurality of burrs 13d is 0.08 mm for example, the depth D1 of the second recess portion 13b is set to be, for example, 0.08 mm or more and 0.1 mm or less.

Further, the diameter W1 of the second recess portion 13b is set to be 3.0 mm for example, the diameter W2 of the third recess portion 13c is set to be 2.5 mm for example, and the depth D2 of the third recess portion 13c is set to be 0.05 to 0.5 mm, for example.

In the above embodiment, the plastic case 13 is provided with the first recess portion 13a which accommodates the SiP memory device 12. The first recess portion 13a is provided with the plurality of the second recess portions 13b in the bottom portion. Each of the plurality of the second recess portions 13b is provided with the third recess portion 13c in the bottom portion. The depth of the second recess portion 13b is set to be greater than the height of the burr 13d formed in the periphery of the third recess portion 13c. Therefore, the tip of the burr 13d formed in the periphery of the third recess portion 13c is located inside the second recess portion 13b and prevented from projecting into the bottom portion of the first recess portion 13a. Consequently, when the SiP memory device 12 is accommodated inside the first recess portion 13a, it is possible to prevent a decrease in adhesive strength between the SiP memory device 12 and the plastic case 13 and thus possible to bond the SiP memory device 12 to the plastic case 13 with sufficient strength.

That is, the plastic case of the USB memory or the memory card incorporating the SiP memory device is formed into a shape defined by the specification and functions as a reinforcement to protect the SiP memory device from external force. Therefore, the SiP memory device accommodated in the plastic case of the present embodiment is secured to the plastic case by the adhesive with sufficient strength.

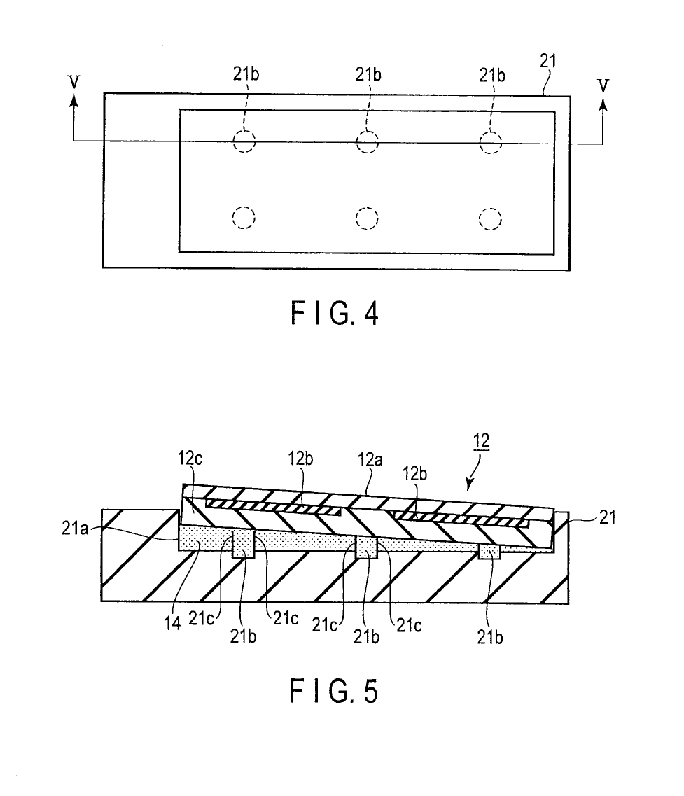

In contrast to this, FIGS. 4 and 5 illustrate a comparative example. In the case of the comparative example, a plastic case 21 comprises a plurality of second recess portions 21b to correspond to a pushpin in a bottom portion of a first recess portion 21a. In this structure, a tip of a burr 21c formed in the periphery of the second recess portion 21b projects into the bottom portion of the first recess portion 21a. Therefore, when the SiP memory device 12 is accommodated inside the first recess portion 21a of the plastic case 21, the SiP memory device 12 becomes tilted by the burr 21c since the height of the burr 21c is not uniform. In this state, the film thickness of the adhesive 14 is not uniform and the adhesive strength between the SiP memory device 12 and the plastic case 21 decreases. To obtain sufficient adhesive strength, therefore, it is necessary to remove the burr 12c.

On the other hand, in the case of the present embodiment, the burr 13d formed in the periphery of the third recess portion 13c is located inside the second recess portion 13b and does not project into the first recess portion 13a configured to accommodate the SiP memory device 12. For this reason, the SiP memory device 12 is prevented from being tilted inside the first recess portion 13a. Therefore, it is possible to make the film thickness of the adhesive 14 uniform and to bond the SiP memory device 12 to the plastic case 12 with sufficient strength.

Further, in the present embodiment, the burr 13d remains inside the second recess portion 13b and increases a contact area with the adhesive 14. Consequently, it is possible to improve the adhesive strength of the adhesive 14 between the plastic case 13 and the semiconductor device 12.

When a burr is created inside the plastic case 13, it is necessary to remove the burr to secure sufficient adhesive strength. However, in the present embodiment, there is no need to remove the burr 13d, and therefore the number of assembling steps can be reduced.

Note that the above embodiment describes the case where an adhesive material is, for example, the adhesive 14. However, the adhesive material is not limited to this, and an adhesive sheet may also be used. In the case of an adhesive sheet, when there is the burr 21c inside the first recess portion 21a as shown in FIG. 5, it is difficult to flatten the adhesive sheet, and thus it is not possible to secure a sufficient contact area between the adhesive sheet and the SiP memory device 12. Therefore, it is difficult to obtain sufficient adhesive strength.

However, in the present embodiment, since the influence of the burr 13d can be eliminated, it is possible to flatten the adhesive sheet, secure a sufficient contact area between the adhesive sheet and the SiP memory device, and obtain sufficient adhesive strength.

Further, in the above embodiment, a semiconductor memory device is described as an example of a SiP type semiconductor device. However, the SiP type semiconductor device is not limited to this, and other semiconductor device may also be applied.

The memory card includes, for example, a NAND type flash memory. The NAND type flash memory includes a memory cell array.

A memory cell array formation may be disclosed in U.S. patent application Ser. No. 12/407,403 filed on Mar. 19, 2009. U.S. patent application Ser. No. 12/407,403, the entire contents of which are incorporated by reference herein.

Further, a memory cell array formation may be disclosed in U.S. patent application Ser. No. 12/406,524 filed on Mar. 18, 2009, and the entire contents of U.S. patent application Ser. No. 12/406,524 are incorporated by reference herein.

Furthermore, a memory cell array formation may be disclosed in U.S. patent application Ser. No. 12/679,991 filed on Mar. 25, 2010, and the entire contents of U.S. patent application Ser. No. 12/679,991 are incorporated by reference herein.

Still furthermore, a memory cell array formation may be disclosed in U.S. patent application Ser. No. 12/532,030 filed on Mar. 23, 2009, and the entire contents of U.S. patent application Ser. No. 12/532,030 are incorporated by reference herein.

Still furthermore, a memory cell array formation may be disclosed in U.S. patent application Ser. No. 10/155,086 filed on May 28, 2002, and the entire contents of U.S. patent application Ser. No. 10/155,086 are incorporated by reference herein.

In addition, a memory cell structure comprises a charge storage layer provided via a tunnel insulating film with a film thickness of 4 to 10 nm on a semiconductor substrate (silicon substrate). The charge storage layer may have a laminated structure of an insulating film such as SiN or SiON with a film thickness of 2 to 3 nm and polysilicon with a film thickness of 3 to 8 nm. To the polysilicon, metal such as Ru may be added. The charge storage layer comprises an insulating film thereon. The insulating film comprises, for example, a silicon dioxide film with a film thickness of 4 to 10 nm sandwiched between a lower layer high-k film with a film thickness of 3 to 10 nm and an upper layer high-k film with a film thickness of 3 to 10 nm. The high-k film may be HfO or the like. In addition, it is possible to make a film thickness of the silicon dioxide film thicker than that of the high-k film. On the insulating film, a control electrode with a film thickness of 30 nm to 70 nm is formed via a work function adjusting material with a film thickness of 3 to 10 nm. Here, the work function adjusting material may be a metal-oxide film such as TaO or a metal-nitride film such as TaN. As the control electrode, W or the like may be used.

Further, an air gap may be formed between memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a substrate;
a semiconductor chip provided on the substrate;
a resin material covering the semiconductor chip and contacting the substrate;
a housing, the housing comprising a first recess portion in which at least the resin material is accommodated, a second recess portion provided in the first recess portion, a third recess portion provided in the second recess portion, and a projection provided in a periphery of the third recess portion;
an adhesive member provided at least in the first recess portion, the adhesive member bonding the housing and the resin material to each other.

2. The electronic device according to claim 1, wherein a depth of the second recess portion is greater than a height of the projection.

3. The electronic device according to claim 2, wherein the depth of the second recess portion is from 0.08 to 0.1 mm.

4. The electronic device according to claim 2, wherein the depth of the third recess portion is from 0.05 to 0.5 mm.

5. The electronic device according to claim 1, wherein the adhesive member is one of an adhesive and an adhesive tape.

6. The electronic device according to claim 1, wherein the electronic device is one of a Universal Serial Bus (USB) memory and a memory card.

7. An electronic device comprising:
a memory comprising,
a substrate;
a semiconductor chip provided on the substrate; and
a resin material covering the semiconductor chip and contacting the substrate;
a housing comprising a first recess portion in which the memory is accommodated, the housing comprising a second recess portion formed in the first recess portion, and a third recess portion formed in the second recess portion, and a projection provided in a periphery of the third recess portion; and
an adhesive member provided in the first recess portion, the adhesive member bonding the housing and the resin material to each other.

8. The electric device according to claim 7, wherein a depth of the second recess portion is greater than a height of the projection.

9. The electric device according to claim 8, wherein the depth of the second recess portion is from 0.08 to 0.1 mm.

10. The electronic device according to claim 8, wherein the depth of the third recess portion is from 0.05 to 0.5 mm.

11. The electronic device according to claim 7, wherein the adhesive member is one of an adhesive and an adhesive tape.

12. The electronic device according to claim 7, wherein the electronic device is one of a USB memory and a memory card.

13. An electronic device comprising:
a case comprising a first recess portion, the case including at least one second recess portion provided in the first recess portion, a third recess portion provided in the second recess portion, and a projection corresponding to the third recess portion;
a System-in-a-Package (SiP) type semiconductor device accommodated in the first recess portion; and
an adhesive member provided in the first recess portion, the adhesive member bonding the housing and the SiP type semiconductor device to each other.

14. The electronic device according to claim 13, wherein a depth of the second recess portion is greater than a height of the projection.

15. The electronic device according to claim 14, wherein the depth of the second recess portion is from 0.08 to 0.1 mm.

16. The electronic device according to claim 14, wherein the depth of the third recess portion is from 0.05 to 0.5 mm.

17. The electronic device according to claim 13, wherein the adhesive member is one of an adhesive and an adhesive tape.

18. The electronic device according to claim 13, wherein the electronic device is one of a USB memory and a memory card.
